(19) United States
(12) Patent Application Publication
(10) Pub. No.: US 2025/0021002 A1
(43) Pub. Date: Jan. 16, 2025

(54) BOTTOM ANTI-REFLECTIVE COATING FOR DEEP ULTRAVIOLET LITHOGRAPHY, PREPARATION METHOD THEREFOR AND USE THEREOF

(71) Applicants: SHANGHAI SINYANG SEMICONDUCTOR MATERIALS CO., LTD., Shanghai (CN); CHINA ADVANCED LITHOGRAPHIC MATERIAL TECHNOLOGY CO. LTD., Shanghai (CN)

(72) Inventors: Shunong FANG, Shanghai (CN); Su WANG, Shanghai (CN); Zhiyue GENG, Shanghai (CN)

(21) Appl. No.: 18/705,591

(22) PCT Filed: Nov. 30, 2021
(86) PCT No.: PCT/CN2021/134374

§ 371 Date: Apr. 29, 2024

(30) Foreign Application Priority Data
Nov. 9, 2021 (CN) 202111322706.6

(51) Int. Cl. G03F 7/039; C08F 222/40; C08F 234/02; G03F 7/004

(52) U.S. Cl. CPC G03F 7/0395; C08F 222/40; C08F 234/02; G03F 7/0045; G03F 7/0048; C08F 2800/20; C08F 2810/20

(57) ABSTRACT

Disclosed in the present invention are a bottom anti-reflective coating for deep ultraviolet lithography, a preparation method therefor and the use thereof. A polymer disclosed in the present invention is prepared by the following method: (1) preheating a solvent I; (2) mixing a monomer as shown in formula (A), a monomer as shown in formula (B), a monomer as shown in formula (C), a cross-linking agent as shown in formula (L), and an initiator and a solvent II to obtain a mixed solution; and (3) adding the mixed solution to a preheated solvent and perform a polymerization reaction, wherein step (1) and step (2) are in no particular order. The bottom anti-reflective coating for deep ultraviolet lithography can reduce the reflectivity, and after the bottom anti-reflective coating is spin-coated with a photoresist, no scum formed by the bottom anti-reflective coating is observed.

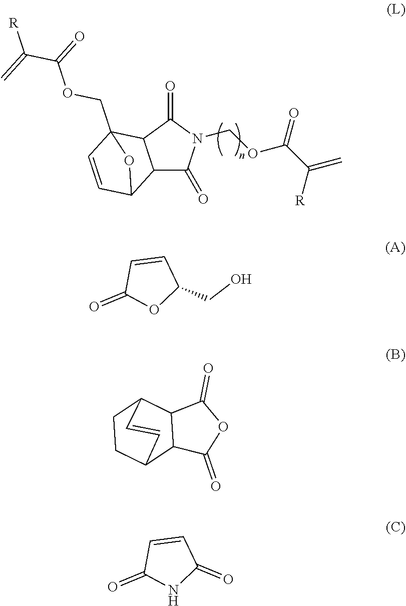

The present application claims priority of Chinese Patent Application No. CN202111322706.6 filed on Nov. 9, 2021, the contents of which are incorporated herein by reference in their entireties.

### TECHNICAL FIELD

The present disclosure relates to a bottom anti-reflective coating for deep ultraviolet lithography, and a preparation method therefor and an application thereof.

### BACKGROUND

In recent years, due to the continuous high integration of large-scale integrated circuits (LSI), and in order to miniaturize the photolithography process, particularly for sub-30 nm node ultra-fine pattern process, the resolution of the photoresist used in photolithography has become a decisive critical factor. Therefore, in the commonly used g-line or i-line regions, the wavelength of the exposure light has been further shortened, and consequently, research on photolithography utilizing deep ultraviolet light, KrF excimer laser, and ArF excimer laser has attracted significant attention.

However, as the wavelength of the exposure light source is shortened, the light interference effects caused by reflected light on the etch layer of the semiconductor substrate increase, and problems such as pattern profile deterioration or size uniformity reduction come out due to undercutting and notching. To prevent these problems, bottom anti-reflective coatings (BARCs) are usually formed between the etch layer and the photoresist film to absorb the exposure light (reflected light).

On the basis of the type of material used, the anti-reflective coating can be classified into inorganic bottom anti-reflective coatings and organic bottom anti-reflective coatings. The inorganic bottom anti-reflective coatings are functioned by optimizing reflectivity, while the organic bottom anti-reflective coatings are by absorbing the light passing through the photoresist film.

Inorganic bottom anti-reflective coatings exhibit excellent conformality to bottom step differences, but are difficult to be removed in subsequent processes, and often have footing issues, where patterns lift off. Therefore, organic bottom anti-reflective coatings have been widely used in recent years.

Compared to inorganic bottom anti-reflective coatings, organic bottom anti-reflective coatings have several advantages: no need of vacuum evaporation equipment, nor chemical vapor deposition (CVD) equipment, nor sputtering equipment for film formation, and excellent absorbency to radioactive rays Therefore, in order to minimize reflectivity as much as possible, it has become important to use a technique that involves setting an organic anti-reflective coating containing light-absorbing organic molecules beneath the photoresist to adjust the reflectivity and prevent reflection from the underlying film. Currently, there is a critical industrial need to develop superior bottom anti-reflective coating (BARC) materials.

### CONTENT OF THE PRESENT INVENTION

The technical problem addressed by the present disclosure is to overcome the existing deficiencies, such as high reflectivity and footing issues associated with bottom anti-reflective coatings. Consequently, the present disclosure provides a bottom anti-reflective coating for deep ultraviolet lithography, as well as a preparation method therefor and use thereof. The bottom anti-reflective coating for deep ultraviolet lithography can adjust the reflectivity. After spin-coating the photoresist on this anti-reflective coating, no residues formed by the bottom anti-reflective coating have been observed.

The present disclosure provides a method for preparing a polymer used to prepare the bottom anti-reflective coating, which includes the following steps:
(1) preheating solvent I;
(2) mixing a monomer of formula (A), a monomer of formula (B), a monomer of formula (C), a cross-linking agent of formula (L), and an initiator and solvent II to obtain a mixed solution;

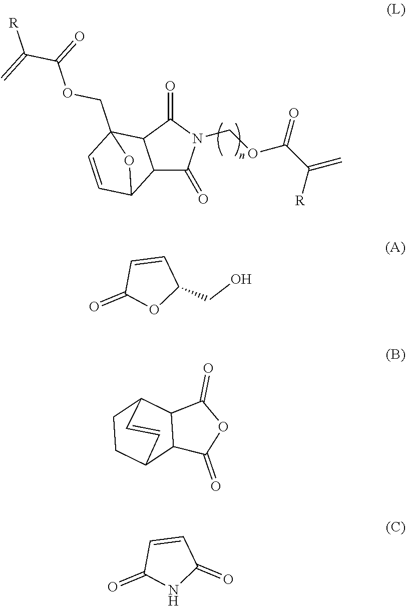

wherein R is H or methyl; n is 1 to 3;
the monomer of formula (A) is used in an amount of 500 to 1000 parts by weight; the monomer of formula (B) is used in an amount of 500 to 1000 parts by weight; the monomer of formula (C) is used in an amount of 500 to 1000 parts by weight; the cross-linking agent of formula (L) is used in an amount of 200 to 250 parts by weight.

(3) adding the mixed solution to a preheated solvent to initiate a polymerization reaction;
wherein step (1) and step (2) are in no particular order.

In the method for preparing the polymer, the solvent I can be an organic solvent, preferably one or more than one of an aromatic solvent, an ether solvent, a ketone solvent, an amide solvent, a sulfoxide solvent, and an ester solvent. The aromatic solvent is preferably toluene and/or benzene. The ether solvent is preferably tetrahydrofuran. The ketone solvent is preferably 2-heptanone. The amide solvent is preferably N,N′-dimethylformamide. The sulfoxide solvent is preferably dimethyl sulfoxide. The ester solvent is preferably ethyl lactate and/or 1-methoxy-2-propyl acetate. The organic solvent is more preferably selected from amide solvents and ketone solvents, such as N,N′-dimethylformamide and 2-heptanone.

In the method for preparing the polymer, for step (1), the solvent is preferably used in an amount of 600 to 1000 parts by weight, more preferably 1000 parts by weight. If more than two types of solvents are used, it is preferred that the parts of different solvents be the same.

In the method for preparing the polymer, for step (1), the solvent I is purged with nitrogen gas. The purging is performed preferably for 20 to 50 minutes, more preferably 30 minutes.

In the method for preparing the polymer, for step (1), the solvent I is preferably preheated at 80 to 100° C., more preferably 90° C.

In the method for preparing the polymer, for step (2), the solvent II can be an organic solvent, preferably one or more than one of aromatic solvents, ether solvents, ketone solvents, amide solvents, sulfoxide solvents, and ester solvents. The aromatic solvent is preferably toluene and/or benzene. The ether solvent is preferably tetrahydrofuran. The ketone solvent is preferably 2-heptanone. The amide solvent is preferably N,N′-dimethylformamide. The sulfoxide solvent is preferably dimethyl sulfoxide. The ester solvent is preferably ethyl lactate and/or 1-methoxy-2-propyl acetate. The organic solvent is more preferably selected from amide solvents and ketone solvents, such as N,N′-dimethylformamide and 2-heptanone.

In the method for preparing the polymer, the solvent II is preferably used in an amount of 6000 to 10000 parts by weight, more preferably 7000 parts by weight. If more than two types of solvents are used, it is preferred that the parts of different solvents be the same.

In the method for preparing the polymer, for step (2), R is preferably methyl.

In the method for preparing the polymer, for step (2), n is preferably 1.

In the method for preparing the polymer, for step (2), the monomer of formula (A) is used preferably in an amount of 650 to 800 parts by weight.

In the method for preparing the polymer, for step (2), the monomer of formula (B) is used preferably in an amount of 650 to 800 parts by weight.

In the method for preparing the polymer, for step (2), the monomer of formula (C) is used preferably in an amount of 650 to 800 parts by weight.

In the method for preparing the polymer, for step (2), the cross-linking agent of formula (L) is used preferably in an amount of 220 parts by weight.

In the method for preparing the polymer, for step (2), the initiator can be a free radical polymerization initiator or a ionic polymerization initiator, preferably 2,2′-azobis(isobutyronitrile) (AIBN), 2,2′-azobis-dimethyl-(2-methylpropionitrile), 2,2′-azobis(4-methoxy-2,4-dimethylvaleronitrile), 2,2′-azobis(2-cyclopropylpropionitrile), 2,2′-azobis(2,4-dimethylvaleronitrile), 1,1′-azobis(cyclohexanecarbonitrile), benzoyl peroxide, tert-butyl peroxybenzoate, di-tert-butyl perphthalate, tert-butyl peroxy-2-ethylhexanoate, tert-butyl peroxypivalate, tert-amyl peroxypivalate, and butyllithium, more preferably 2,2′-azobis(isobutyronitrile) and/or 2,2′-azobis-dimethyl-(2-methylpropionitrile), further more preferably 2,2′-azobis(isobutyronitrile).

In the method for preparing the polymer, for step (2), the initiator is preferably used in an amount of 1 to 10 wt %, more preferably 3 to 5 wt %; where wt % refers to the ratio of the weight of the initiator to the combined weight of all monomers.

In the method for preparing the polymer, for step (2), the mixed solution is purged with nitrogen gas. The purging is performed preferably for 30 minutes.

In the method for preparing the polymer, for step (3), the preferred method of adding components is using a peristaltic pump. The addition lasts preferably for 2.5 hours.

In the method for preparing the polymer, for step (3), the polymerization reaction is performed at a temperature of 50 to 200° C., preferably 60 to 150° C., more preferably 80 to 120° C.

In the method for preparing the polymer, for step (3), the duration of polymerization reaction is preferably 5 to 7 hours, more preferably 6 hours.

In the method for preparing the polymer, the polymerization reaction can employ conventional post-treatment techniques in the art to separate and purify the polymer, or the reaction mixture can be used directly as raw material without separation or purification.

In the method for preparing the polymer, the polymerization reaction can employ conventional post-treatment techniques including the following steps: cooling, adding organic solvents to the reaction liquid, removing the supernatant, dissolving the remaining reaction mixture in tetrahydrofuran (THF), pouring the resulting solution into water, filtering, and drying.

In the method for preparing the polymer, during the post-treatment of the polymerization reaction, the preferred way of cooling is to cool the reaction mixture to room temperature.

In the method for preparing the polymer, during the post-treatment of the polymerization reaction, the organic solvent is preferably a poor solvent for the polymer but a good solvent for the solvent in which the polymer dissolves, more preferably n-hexane or n-heptane, most preferably n-heptane. The organic solvent is used in an amount of 60000 parts by weight.

In the method for preparing the polymer, during the post-treatment of the polymerization reaction, water is used in an amount of 100000 parts by weight.

In the method for preparing the polymer, during the post-treatment of the polymerization reaction, the preferred way of filtration is filtration under reduced pressure.

In the method for preparing the polymer, during the post-treatment of the polymerization reaction, the preferred drying conditions involve drying overnight in a vacuum oven. The temperature of the vacuum oven is preferably set at 45° C.

The present disclosure further aims to provide a polymer used for preparing the bottom anti-reflective coating, wherein the polymer is prepared using the above method.

The polymer may be of any structure, such as a random copolymer or block copolymer.

In the polymer, the molecular weight has no specific limitation as it can be regulated through various polymerization conditions such as polymerization duration and temperature, monomer concentration, the initiator used in the reaction, and the reaction solvent. When the polymerization reaction is an ionic polymerization, the molecular weight of the polymer preferably has a narrow molecular weight distribution.

In the polymer, when the molecular weight is measured by gel permeation chromatography (GPC) using standard polystyrene, the weight-average molecular weight is preferably between 2000 and 5000000. Considering film-forming ability, solubility, and thermal stability, the weight-average molecular weight is more preferably 3000 to 100000, most preferably 5220, 5237, 5974, 6155, 6166, 6355, 6589, or 6931.

In the polymer, the number-average molecular weight is preferably between 3000 and 6000, more preferably 3009, 3479, 4593, 4783, 5609, 5794, or 5885.

In the polymer, the polydispersity index (PDI) is preferably between 1 and 2, more preferably 1.10, 1.12, 1.14, 1.20, 1.29, 1.38, 1.72, or 1.73.

The present disclosure provides a composition used for preparing the bottom anti-reflective coating, wherein the composition comprises the above mentioned polymer, solvent, and photoacid generator.

In the composition, the solvent can be any kind of solvent, and is preferably one or more than one of an ether solvent, an ester solvent, an alcohol solvent, an aromatic solvent, a ketone solvent, and an amide solvent. The ether solvent is preferably one or more than one of propylene glycol monobutyl ether, ethylene glycol monomethyl ether, ethylene glycol monoethyl ether, diethylene glycol monomethyl ether, diethylene glycol monoethyl ether, and propylene glycol monomethyl ether. The ester solvent is preferably one or more than one of propylene glycol monobutyl ether acetate, methyl cellosolve acetate, ethyl cellosolve acetate, propylene glycol monomethyl ether acetate, propylene glycol propyl ether acetate, ethyl 2-hydroxypropionate, ethyl 2-hydroxy-2-methylpropionate, ethyl ethoxyacetate, ethyl hydroxyacetate, methyl 2-hydroxy-3-methylbutyrate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, and butyl lactate. The alcohol solvent is preferably propylene glycol. The aromatic solvent is preferably toluene and/or xylene. The ketone solvent is preferably one or more than one of 2-butanone, cyclopentanone, and cyclohexanone. The amide solvent is preferably one or more than one of N,N-dimethylformamide, N,N-dimethylacetamide, and N-methyl-2-pyrrolidone. The solvent is more preferably propylene glycol monobutyl ether and/or propylene glycol monobutyl ether acetate.

In the composition, the quantity of the solvent used is sufficient to dissolve all components, preferably 1000 to 2500 parts by weight, more preferably 1200 to 2000 parts by weight, most preferably 1500 to 1800 parts by weight.

In the composition, the photoacid generator is capable of assisting the crosslinked polymer to decrosslink upon exposure, thereby endowing the target bottom anti-reflective coating with developability and photosensitivity.

In the composition, the photoacid generator can be any compound capable of generating acid when exposed to KrF excimer laser (wavelength: 248 nm), ArF excimer laser (wavelength: 193 nm), or similar sources, preferably one or more than one of an onium salt, a sulfonylimide derivative, and a disulfonyl diazomethane compound.

In the composition, for the photoacid generator, the onium salt is preferably an iodonium salt, a sulfonium salt, or a crosslinkable onium salt. The iodonium salt is preferably one or more than one of diphenyliodonium hexafluorophosphate, diphenyliodonium trifluoromethanesulphonate, diphenyliodonium nonafluorobutanesulfonate, diphenyliodonium perfluorooctanesulfonate, diphenyliodonium camphorsulfonate, bis(4-tert-butylphenyl)iodonium camphorsulfonate, and bis(4-tert-butylphenyl)iodonium trifluoromethanesulfonate. The sulfonium salt is preferably one or more than one of triphenylsulfonium hexafluoroantimonate, triphenylsulfonium nonafluorobutanesulfonate, triphenylsulfonium camphorsulfonate, and triphenylsulfonium trifluoromethanesulfonate, more preferably triphenylsulfonium hexafluoroantimonate and/or triphenylsulfonium trifluoromethanesulfonate. The crosslinkable onium salt is preferably one or more than one of bis(4-hydroxyphenyl)(phenyl)sulfonium trifluoromethanesulfonate, bis(4-hydroxyphenyl)(phenyl)sulfonium 1,1,2,2,3,3,4,4,4-nonafluorobutane-1-sulfonate, phenylbis(4-(2-(vinyloxy)ethoxy)-phenyl)sulfonium 1,1,2,2,3,3,4,4-octafluorobutane-1,4-disulfonate, and tris(4-(2-(vinyloxy)ethoxy)-phenyl)sulfonium 1,1,2,2,3,3,4,4-octafluorobutane-1,4-disulfonate.

In the composition, for the photoacid generator, the sulfonylimide derivative is preferably one or more than one of N-(trifluoromethanesulfonyloxy) succinimide, N-(fluorobutanesulfonyloxy) succinimide, N-(camphorsulfonyloxy) succinimide, and N-(trifluoromethanesulfonyloxy) naphthalenediimide.

In the composition, for the photoacid generator, the disulfonyl diazomethane compound is preferably one or more than one of bis(trifluoromethylsulfonyl) diazomethane, bis(cyclohexylsulfonyl) diazomethane, bis(phenylsulfonyl) diazomethane, bis(p-toluenesulfonyl) diazomethane, bis(2,4-dimethylphenylsulfonyl) diazomethane, and methylsulfonyl-p-toluenesulfonyl diazomethane.

In the composition, the photoacid generator is preferably used in an amount of 0.01 to 20 parts by weight, more preferably 1 to 15 parts by weight, such as 5 to 10 parts by weight.

In the composition, the polymer is used in an amount of 100 parts by weight.

The composition may also contain other additional components. The additional components include polymers other than those mentioned above, a surfactant, and a leveling agent.

The quantity of these additional components in the composition is not specifically limited and can be appropriately determined based on the target coating.

The present disclosure further aims to provide a method for preparing the composition for the bottom anti-reflective coating, wherein the method comprises the following steps: mixing the various components of the composition as described above.

In the method for preparing the composition, the preferred method of mixing is stirring, and the preferred mixing conditions involve stirring at room temperature for 30 minutes.

In the method for preparing the composition, following the mixing, an additional step of filtration may be included. The filtration can be conducted using a filter, with the preferred pore size of the filter ranging from 0.2 to 0.05 m, and more preferably being 0.05 m.

In the method for preparing the composition, the composition prepared thereby exhibits excellent storage stability, allowing it to be stored for much longer periods at room temperature.

The present disclosure further aims to provide a bottom anti-reflective coating prepared from the composition as described above.

The present disclosure further aims to provide a method for preparing the bottom anti-reflective coating, wherein the method comprises the following steps: casting the composition as described above onto a semiconductor substrate followed by baking to obtain the bottom anti-reflective coating.

In the method for preparing the bottom anti-reflective coating, the preferred casting tool is a spin coater or a coater, more preferably a spin coater.

In the method for preparing the bottom anti-reflective coating, the semiconductor substrate is preferably one of a substrate coated with silicon/dioxide, a silicon nitride substrate, a silicon wafer substrate, a glass substrates, or an ITO substrate, more preferably a silicon wafer substrate.

In the method for preparing the bottom anti-reflective coating, the baking is performed preferably at a temperature of 80 to 250° C., more preferably 100 to 250° C., most preferably 190° C.

In the method for preparing the bottom anti-reflective coating, the baking is performed preferably for 0.3 to 5 minutes, more preferably 0.5 to 2 minutes, most preferably 1 minute.

The present disclosure further provides a method for forming a photoresist pattern on the bottom anti-reflective coating, which includes the following steps:
S1: coating the bottom anti-reflective coating with a photoresist;
S2: soft baking;
S3: exposure;
S4: baking;
S5: development.

In the method for forming a photoresist pattern on the bottom anti-reflective coating, the photoresist is conventional in the field, preferably positive photoresists, negative photoresists, or negative tone development (NTD) photoresists, more preferably positive photoresists, such as 248 nm positive photoresist SEPR-430™ (manufactured by Shin-Etsu) or 193 nm positive photoresist (TOK Corporation, tai-6990 PH).

In the method for forming a photoresist pattern on the bottom anti-reflective coating, the soft baking is performed at a temperature of 100 to 140° C., more preferably 120° C. The soft baking is performed for 0.5 to 2 minutes, more preferably 60 seconds.

In the method for forming a photoresist pattern on the bottom anti-reflective coating, the exposure light used can be conventional in the field, with preferred wavelengths ranging from 13.5 to 248 nm. More preferably, the light sources are KrF excimer laser (wavelength: 248 nm), ArF excimer laser (wavelength: 193 nm), or extreme UV light (wavelength: 13.5 nm).

In the method for forming a photoresist pattern on the bottom anti-reflective coating, the baking is performed at a temperature of 80 to 150° C., more preferably 100 to 140° C., most preferably 130° C.

In the method for forming a photoresist pattern on the bottom anti-reflective coating, the baking is performed preferably for 0.3 to 5 minutes, more preferably 0.5 to 2 minutes, most preferably 60 seconds.

In the method for forming a photoresist pattern on the bottom anti-reflective coating, the development involves a developer solution. This developer solution can easily dissolve and remove the bottom anti-reflective coating.

The developer solution can be an alkaline developer solution, preferably an aqueous solution of alkali metal hydroxides, quaternary ammonium hydroxides, or amines. The aqueous solution of alkali metal hydroxides is preferably an aqueous solution of potassium hydroxide or sodium hydroxide. The aqueous solution of quaternary ammonium hydroxides is preferably an aqueous solution of tetramethylammonium hydroxide (TMAH), tetraethylammonium hydroxide, or choline. The aqueous solution of amines is preferably an aqueous solution of ethanolamine, propylamine, or ethylenediamine. The developer solution is more preferably a 2.38 wt % aqueous solution of tetramethylammonium hydroxide.

In the method for forming a photoresist pattern on the bottom anti-reflective coating, the developer solution may also contain a surfactant.

In the method for forming a photoresist pattern on the bottom anti-reflective coating, the temperature for the developer solution preferably ranges from 5 to 50° C., more preferably 25 to 40° C.

In the method for forming a photoresist pattern on the bottom anti-reflective coating, the development duration is preferably 10 to 300 seconds, more preferably 30 to 60 seconds.

These preferred conditions can be combined in any manner that is consistent with common knowledge in the field, to achieve the preferred examples of the present disclosure.

All reagents and raw materials used in the present disclosure are commercially available.

The positive advancements of the present disclosure include: (1) The invention provides a bottom anti-reflective coating for deep ultraviolet lithography that effectively reduces reflectivity. (2) The deep ultraviolet lithography bottom anti-reflective coating delivers exceptional performance. After the bottom anti-reflective coating is spin-coated with a photoresist, the cross-sectional shape of the pattern exposed in the irradiated areas shows that the coating functions flawlessly in practical applications, and no residue formed by the bottom anti-reflective coating is observed.

### DETAILED DESCRIPTION OF THE PREFERRED EMBODIMENT

The present disclosure is further described below by way of examples; however, the present disclosure is not limited to the scope of the described examples. For the experimental methods in which no specific conditions are specified in the following examples, selections are made according to conventional methods and conditions or according to the product instructions.

In the description of the examples, “parts” and “%” respectively refer to “parts by weight” and “wt %” unless otherwise specified.

### Preparation of Polymer

The preparation of polymers P1 to P8 and comparative polymers CP1 to CP7 follows the steps outlined below. The quantities of monomers of formula (A), formula (B), formula (C), and the cross-linking agent of formula (L) required for each polymer are detailed in Table 1.

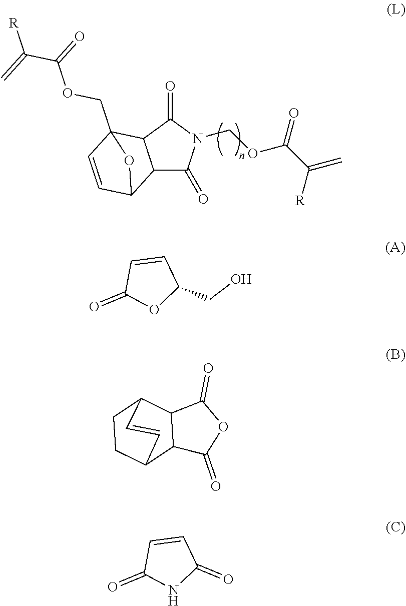

In a reaction vessel equipped with a stirrer, condenser, heater, and thermostat, N,N′-dimethylformamide (500 parts by weight) and methyl isobutyl ketone (500 parts by weight) were placed. The solvents were purged with nitrogen for 30 minutes, then heated to 90° C. Separately, the monomers of formulas (A), (B), and (C), the cross-linking agent of formula (L), 2,2′-azobis(isobutyronitrile) (AIBN, a free radical polymerization initiator, 100 parts by weight), N,N′-dimethylformamide (3500 parts by weight), and methyl isobutyl ketone (3500 parts by weight) were placed in a sample container and stirred. The resulting mixture solution was purged with nitrogen for 30 minutes.

The mixture solution was then introduced into the reaction vessel over a period of 2.5 hours using a peristaltic pump. After the introduction was complete, the reaction mixture was maintained at 80° C. for 6 hours.

Upon cooling to room temperature, the mixture was poured into n-heptane (60000 parts by weight). The supernatant was removed, and the remaining reaction mixture was dissolved in tetrahydrofuran (THF, 6000 parts by weight). The resulting solution was poured into water (100000 parts by weight), forming a white precipitate. The precipitate was separated by reduced filtration and dried overnight in a vacuum oven at 45° C.

After drying, the copolymer was obtained as a form of white powder. The weight-average molecular weight (Mw) and number-average molecular weight of the product were measured by Gel Permeation Chromatography (GPC) using THE as the solvent, and the polydispersity index (PDI) was calculated.

TABLE 1

| | Monomer | Monomer | Monomer | Cross-linking | | | | | |
|---|---|---|---|---|---|---|---|---|---|
| Polymer | (A) | (B) | (C) | agent (L) | Parts of | | | | |
| No | Parts | Parts | Parts | Parts | monomer | Yield | Mw | Mn | PDI |
| P1 | 650 | 650 | 650 | 250 | 1531 | 94% | 5220 | 3009 | 1.73 |
| P2 | 1000 | 500 | 500 | 250 | 1836 | 91% | 5237 | 4593 | 1.14 |
| P3 | 500 | 1000 | 500 | 200 | 1738 | 79% | 6589 | 5885 | 1.12 |
| P4 | 500 | 500 | 1000 | 220 | 2387 | 95% | 6931 | 5794 | 1.20 |
| P5 | 800 | 800 | 800 | 200 | 1671 | 84% | 6355 | 4593 | 1.38 |
| P6 | 650 | 800 | 650 | 250 | 2048 | 86% | 6155 | 5609 | 1.10 |
| P7 | 650 | 650 | 650 | 200 | 1867 | 91% | 6166 | 4783 | 1.29 |
| P8 | 650 | 650 | 650 | 250 | 1626 | 83% | 5974 | 3479 | 1.72 |
| CP1 | 450 | 450 | 450 | 220 | 1598 | 84% | 6595 | 4944 | 1.33 |
| CP2 | 1200 | 1200 | 1200 | 220 | 1952 | 83% | 5644 | 5213 | 1.08 |
| CP3 | 800 | 1200 | 800 | 220 | 2267 | 83% | 5401 | 5628 | 0.96 |
| CP4 | 1200 | 800 | 800 | 220 | 1515 | 87% | 6306 | 5327 | 1.18 |
| CP5 | 800 | 800 | 1200 | 220 | 2380 | 89% | 6707 | 5763 | 1.16 |
| CP6 | 650 | 650 | 650 | 150 | 1863 | 81% | 5020 | 4521 | 1.11 |
| CP7 | 650 | 650 | 650 | 350 | 1746 | 80% | 5677 | 5322 | 1.07 |

### Examples 1-16, Comparative Examples 17-30: Preparation of Bottom Anti-Reflective Coatings

Solvent and photoacid generator were added to the polymers prepared as described above, the quantities used are listed in Table 2. The resulting mixture was stirred at room temperature for 30 minutes, then filtered through a 0.05 μm pore size filter to prepare a solution of the bottom anti-reflective coating composition.

The prepared composition was cast onto silicon microchip wafers using a spin coating process. The coatings were then cross linked by baking on a vacuum hotplate at 190° C. for 60 seconds, resulting in the bottom anti-reflective coatings for Examples 1-16 and Comparative Examples 1-14.

The polymers used, as listed in Table 2, were polymers P1 to P8 and CP1 to CP7, which had been prepared as outlined in Table 1.

TABLE 2

| | Bottom | | | | | | |
|---|---|---|---|---|---|---|---|
| | anti- | | | | | | |
| | reflective | | | | Parts of | Parts of | |
| Example | coating | | Parts of | Photoacid | photoacid | photoacid | Parts of |
| No. | No. | Polymer | polymer | generator | generator | generator | solvent |
| Example 1 | B1 | P1 | 100 | triphenylsulfonium | 15 | propylene | 2000 |
| | | | | hexafluoroantimonate | | glycol | |
| | | | | | | monobutyl | |
| | | | | | | ether | |
| Example 2 | B2 | P2 | 100 | triphenylsulfonium | 10 | propylene | 1800 |
| | | | | hexafluoroantimonate | | glycol | |
| | | | | | | monobutyl | |
| | | | | | | ether | |
| Example 3 | B3 | P3 | 100 | triphenylsulfonium | 5 | propylene | 1500 |
| | | | | hexafluoroantimonate | | glycol | |
| | | | | | | monobutyl | |
| | | | | | | ether | |
| Example 4 | B4 | P4 | 100 | triphenylsulfonium | 1 | propylene | 1200 |
| | | | | hexafluoroantimonate | | glycol | |
| | | | | | | monobutyl | |
| | | | | | | ether | |
| Example 5 | B5 | P5 | 100 | triphenylsulfonium | 15 | propylene | 2000 |
| | | | | hexafluoroantimonate | | glycol | |
| | | | | | | monobutyl | |
| | | | | | | ether | |
| Example 6 | B6 | P6 | 100 | triphenylsulfonium | 10 | propylene | 1800 |
| | | | | hexafluoroantimonate | | glycol | |
| | | | | | | monobutyl | |
| | | | | | | ether | |
| Example 7 | B7 | P7 | 100 | triphenylsulfonium | in 5 | propylene | 1500 |
| | | | | hexafluoroantimonate | | glycol | |
| | | | | | | monobutyl | |
| | | | | | | ether | |
| Example 8 | B8 | P8 | 100 | triphenylsulfonium | 1 | propylene | 1200 |
| | | | | hexafluoroantimonate | | glycol | |
| | | | | | | monobutyl | |
| | | | | | | ether | |
| Example 9 | B9 | P1 | 100 | triphenylsulfonium | 15 | propylene | 2000 |
| | | | | trifluoromethanesulfonate | | glycol | |
| | | | | | | monobutyl | |
| | | | | | | ether | |
| | | | | | | acetate | |
| Example 10 | B10 | P2 | 100 | triphenylsulfonium | 10 | propylene | 1800 |
| | | | | trifluoromethanesulfonate | | glycol | |
| | | | | | | monobutyl | |
| | | | | | | ether | |
| | | | | | | acetate | |
| Example 11 | B11 | P3 | 100 | triphenylsulfonium | 5 | propylene | 1500 |
| | | | | trifluoromethanesulfonate | | glycol | |
| | | | | | | monobutyl | |
| | | | | | | ether | |
| | | | | | | acetate | |
| Example 12 | B12 | P4 | 100 | triphenylsulfonium | 1 | propylene | 1200 |
| | | | | trifluoromethanesulfonate | | glycol | |
| | | | | | | monobutyl | |
| | | | | | | ether | |
| | | | | | | acetate | |
| Example 13 | B13 | P5 | 100 | triphenylsulfonium | 15 | propylene | 2000 |
| | | | | trifluoromethanesulfonate | | glycol | |
| | | | | | | monobutyl | |
| | | | | | | ether | |
| | | | | | | acetate | |
| Example 14 | B14 | P6 | 100 | triphenylsulfonium | 10 | propylene | 1800 |
| | | | | trifluoromethanesulfonate | | glycol | |
| | | | | | | monobutyl | |
| | | | | | | ether | |
| | | | | | | acetate | |
| Example 15 | B15 | P7 | 100 | triphenylsulfonium | 5 | propylene | 1500 |
| | | | | trifluoromethanesulfonate | | glycol | |
| | | | | | | monobutyl | |
| | | | | | | ether | |
| | | | | | | acetate | |
| Example 16 | B16 | P8 | 100 | triphenylsulfonium | 1 | propylene | 1200 |
| | | | | trifluoromethanesulfonate | | glycol | |
| | | | | | | monobutyl | |
| | | | | | | ether | |
| | | | | | | acetate | |
| Comparative | CB1 | CP1 | 100 | triphenylsulfonium | 15 | propylene | 2000 |
| example 1 | | | | hexafluoroantimonate | | glycol | |
| | | | | | | monobutyl | |
| | | | | | | ether | |
| Comparative | CB2 | CP2 | 100 | triphenylsulfonium | 10 | propylene | 1800 |
| example 2 | | | | hexafluoroantimonate | | glycol | |
| | | | | | | monobutyl | |
| | | | | | | ether | |
| Comparative | CB3 | CP3 | 100 | triphenylsulfonium | 5 | propylene | 1500 |
| example 3 | | | | hexafluoroantimonate | | glycol | |
| | | | | | | monobutyl | |
| | | | | | | ether | |
| Comparative | CB4 | CP4 | 100 | triphenylsulfonium | 1 | propylene | 1200 |
| example 4 | | | | hexafluoroantimonate | | glycol | |
| | | | | | | monobutyl | |
| | | | | | | ether | |
| Comparative | CB5 | CP5 | 100 | triphenylsulfonium | 15 | propylene | 2000 |
| example 5 | | | | hexafluoroantimonate | | glycol | |
| | | | | | | monobutyl | |
| | | | | | | ether | |
| Comparative | CB6 | CP6 | 100 | triphenylsulfonium | 10 | propylene | 1800 |
| example 6 | | | | hexafluoroantimonate | | glycol | |
| | | | | | | monobutyl | |
| | | | | | | ether | |
| Comparative | CB7 | CP7 | 100 | triphenylsulfonium | 5 | propylene | 1500 |
| example 7 | | | | hexafluoroantimonate | | glycol | |
| | | | | | | monobutyl | |
| | | | | | | ether | |
| Comparative | CB8 | CP1 | 100 | triphenylsulfonium | 15 | propylene | 2000 |
| example 8 | | | | trifluoromethanesulfonate | | glycol | |
| | | | | | | monobutyl | |
| | | | | | | ether | |
| | | | | | | acetate | |
| Comparative | CB9 | CP2 | 100 | triphenylsulfonium | 10 | propylene | 1800 |
| example 9 | | | | trifluoromethanesulfonate | | glycol | |
| | | | | | | monobutyl | |
| | | | | | | ether | |
| | | | | | | acetate | |
| Comparative | CB10 | CP3 | 100 | triphenylsulfonium | 5 | propylene | 1500 |
| example 10 | | | | trifluoromethanesulfonate | | glycol | |
| | | | | | | monobutyl | |
| | | | | | | ether | |
| | | | | | | acetate | |
| Comparative | CB11 | CP4 | 100 | triphenylsulfonium | 1 | propylene | 1200 |
| example 11 | | | | trifluoromethanesulfonate | | glycol | |
| | | | | | | monobutyl | |
| | | | | | | ether | |
| | | | | | | acetate | |
| Comparative | CB12 | CP5 | 100 | triphenylsulfonium | 15 | propylene | 2000 |
| example 12 | | | | trifluoromethanesulfonate | | glycol | |
| | | | | | | monobutyl | |
| | | | | | | ether | |
| | | | | | | acetate | |
| Comparative | CB13 | CP6 | 100 | triphenylsulfonium | 10 | propylene | 1800 |
| example 13 | | | | trifluoromethanesulfonate | | glycol | |
| | | | | | | monobutyl | |
| | | | | | | ether | |
| | | | | | | acetate | |
| Comparative | CB14 | CP7 | 100 | triphenylsulfonium | 5 | propylene | 1500 |
| example 14 | | | | trifluoromethanesulfonate | | glycol | |
| | | | | | | monobutyl | |
| | | | | | | ether | |
| | | | | | | acetate | |

### Application and Effect Examples

### 1. Optical Performance Testing

The bottom anti-reflective coatings were measured for their refractive index (n value) and extinction coefficient (k value) at wavelengths of 248 nm and 193 nm using an ellipsometer.

### 2. Developability Performance Testing

(1) Method for forming photoresist patterns and development performance testing with exposure wavelength of 248 nm on the bottom anti-reflective coating

A commercially available 248 nm positive photoresist (SEPR-430™, manufactured by Shin-Etsu) was spin-coated onto the obtained anti-reflective coating. The photoresist layer was soft-baked on a vacuum hotplate at 120° C., then exposed to 248 nm radiation by photomask imaging. After a post-exposure bake at 130° C. for 60 seconds, the photoresist layer was developed using a 2.38 wt % TMAH aqueous solution. As a result of this development process, the photoresist and the underlying bottom anti-reflective coating were removed in the regions defined by the photomask. The solvent resistance of the anti-reflective coating in the exposed areas was observed, along with the cross-sectional shape of the pattern. Additionally, check if there has any formation of residues from the bottom anti-reflective coating.

(2) Method for Forming Photoresist Patterns and Development Performance Testing with Exposure Wavelength of 193 nm on the Bottom Anti-Reflective Coating

A commercially available 193 nm positive photoresist (tai-6990 PH, manufactured by TOK) was spin-coated onto the obtained bottom anti-reflective coating. The photoresist layer was soft-baked on a vacuum hotplate at 120° C., then exposed to 193 nm radiation by photomask imaging. After a post-exposure bake at 130° C. for 60 seconds, the photoresist layer was developed using a 2.38 wt % TMAH aqueous solution. As a result of this development process, the photoresist and the underlying bottom anti-reflective coating were removed in the regions defined by the photomask. The solvent resistance of the anti-reflective coating in the exposed areas was observed, along with the cross-sectional shape of the pattern. Additionally, check if there has any formation of residues from the bottom anti-reflective coating.

The effectiveness of the anti-reflective coatings B1 to B16 prepared in Examples 1-16 and the comparative coatings CB1 to CB14 prepared in Comparative Examples 1-14 is detailed in Table 3.

TABLE 3

| | | | | | Develop ability performance | | | |
|---|---|---|---|---|---|---|---|---|
| | Optical properties | | | | 248 nm | | 193 nm | |
| Anti- | 248 nm | | 193 nm | | Cross- | | Cross- | |
| reflective | Refractive | Extinction | Refractive | Extinction | section | | section | |
| coating | index | coefficient | index | coefficient | shape of | | shape of | |
| No. | (n) | (k) | (n) | (k) | pattern | Residue | pattern | Residue |
| B1 | 1.87 | 0.50 | 1.94 | 0.31 | A | A | A | A |
| B2 | 1.90 | 0.48 | 1.88 | 0.46 | A | A | A | A |
| B3 | 1.97 | 0.38 | 1.91 | 0.31 | A | A | A | A |
| B4 | 1.88 | 0.49 | 1.86 | 0.47 | A | A | A | A |
| B5 | 1.97 | 0.44 | 1.99 | 0.33 | A | A | A | A |
| B6 | 1.92 | 0.50 | 1.92 | 0.31 | A | A | A | A |
| B7 | 1.86 | 0.42 | 1.96 | 0.48 | A | A | A | A |
| B8 | 1.98 | 0.50 | 1.91 | 0.46 | A | A | A | A |
| B9 | 1.82 | 0.50 | 1.92 | 0.47 | A | A | A | A |
| B10 | 1.87 | 0.41 | 1.88 | 0.33 | A | A | A | A |
| B11 | 1.80 | 0.48 | 1.95 | 0.34 | A | A | A | A |
| B12 | 1.97 | 0.37 | 1.96 | 0.44 | B | A | B | A |
| B13 | 1.89 | 0.30 | 1.97 | 0.41 | A | A | A | A |
| B14 | 1.97 | 0.36 | 1.94 | 0.50 | A | A | A | A |
| B15 | 1.84 | 0.48 | 1.88 | 0.49 | A | A | A | A |
| B16 | 1.82 | 0.34 | 1.96 | 0.33 | A | A | A | A |
| CB1 | 1.83 | 0.23 | 1.69 | 0.23 | C | C | C | C |
| CB2 | 1.83 | 0.24 | 1.72 | 0.22 | C | C | C | C |
| CB3 | 1.73 | 0.34 | 1.74 | 0.33 | C | C | C | C |
| CB4 | 1.80 | 0.21 | 1.71 | 0.32 | C | C | C | C |
| CB5 | 1.62 | 0.23 | 1.74 | 0.23 | B | C | B | C |
| CB6 | 1.60 | 0.22 | 1.67 | 0.28 | C | C | C | C |
| CB7 | 1.81 | 0.34 | 1.85 | 0.30 | C | C | C | C |
| CB8 | 1.75 | 0.27 | 1.64 | 0.27 | C | C | C | C |
| CB9 | 1.79 | 0.21 | 1.68 | 0.23 | B | C | B | C |
| CB10 | 1.75 | 0.22 | 1.76 | 0.28 | C | C | C | C |
| CB11 | 1.79 | 0.35 | 1.60 | 0.20 | C | C | C | C |
| CB12 | 1.68 | 0.23 | 1.67 | 0.31 | C | C | C | C |
| CB13 | 1.80 | 0.34 | 1.83 | 0.22 | C | C | C | C |
| CB14 | 1.64 | 0.35 | 1.64 | 0.31 | C | C | C | C |

Note on Pattern Cross-Section Shapes: A: The photoresist and the bottom anti-reflective coating both exhibit vertical rectangular side profiles perpendicular to the substrate surface. B: The photoresist and the bottom anti-reflective coating both exhibit side profiles that are slightly inclined, rather than vertical, to the substrate surface, but this poses no practical issues. C: The photoresist and the bottom anti-reflective coating both exhibit side profiles that are interlocking relative to the substrate surface.

Note on Residue Formation: A: No residues observed from the bottom anti-reflective coating. B: Slight residues observed from the bottom anti-reflective coating, but these are negligible for practical purposes. C: Significant residues observed from the bottom anti-reflective coating.

Based on Table 3, it is evident that the obtained bottom anti-reflective coatings effectively reduce reflectivity. Both the 193 nm and 248 nm positive photoresists were spin-coated on the obtained bottom anti-reflective coatings except for B12. In the areas exposed to radiation, the cross-section shape of the patterns showed that both the photoresist and the bottom anti-reflective coatings exhibited vertical rectangular side profiles perpendicular to the substrate surface, and no residues formed by the bottom anti-reflective coatings were observed. On the obtained bottom anti-reflective coating B12, both the 193 nm and 248 nm positive photoresists were applied. In the areas exposed to radiation, the cross-section shape of the patterns showed that both the photoresist and the bottom anti-reflective coating exhibited side profiles that were slightly inclined, rather than perpendicular, to the substrate surface. However, this posed no practical issues, and no residues formed by the bottom anti-reflective coating were observed. In the comparative examples, the cross-section shapes of the patterns on most of the samples showed that both the photoresist and the bottom anti-reflective coating had interlocking side profiles relative to the substrate surface. A significant amount of residues formed by the bottom anti-reflective coating was observed, which adversely affected usability.

In conclusion, the present disclosure has developed a bottom anti-reflective coating for deep ultraviolet lithography that effectively reduces reflectivity. After the bottom anti-reflective coating is spin-coated with a photoresist, the cross-sectional shape of the pattern in the irradiated areas shows that the coating functions flawlessly in practical applications, and no residue formed by the bottom anti-reflective coating is observed.

1. A method for preparing a polymer used to prepare a bottom anti-reflective coating, wherein the method comprises the following steps:
(1) preheating solvent I;
(2) mixing a monomer of formula (A), a monomer of formula (B), a monomer of formula (C), a cross-linking agent of formula (L), and an initiator and solvent II to obtain a mixed solution; 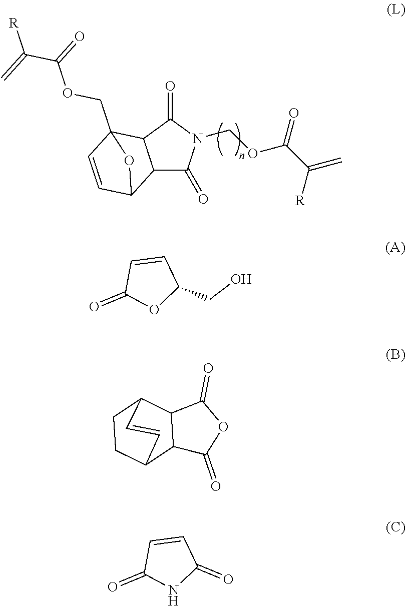
wherein R is H or methyl; n is 1 to 3;
the monomer of formula (A) is used in an amount of 500 to 1000 parts by weight; the monomer of formula (B) is used in an amount of 500 to 1000 parts by weight; the monomer of formula (C) is used in an amount of 500 to 1000 parts by weight; the cross-linking agent of formula (L) is used in an amount of 200 to 250 parts by weight;
(3) adding the mixed solution to a preheated solvent to initiate a polymerization reaction;
wherein step (1) and step (2) are in no particular order.

2. The method for preparing the polymer according to claim 1, wherein, for the step (1), the solvent I is an organic solvent;
or, for the step (1), the solvent I is used in an amount of 600 to 1000 parts by weight;
or, for the step (1), the solvent I is purged with nitrogen gas;
or, for the step (1), the solvent I is preheated at 80 to 100° C.;
or, for the step (2), the solvent II is an organic solvent;
or, for the step (2), the solvent I is used in an amount of 6000 to 10000 parts by weight;
or, for the step (2), R is methyl;
or, for the step (2), n is 1; or, for step (2), the monomer of formula (A) is used in an amount of 650 to 800 parts by weight;
or, for the step (2), the monomer of formula (B) is used in an amount of 650 to 800 parts by weight;
or, for the step (2), the monomer of formula (C) is used in an amount of 650 to 800 parts by weight;
or, for the step (2), the cross-linking agent of formula (L) is used in an amount of 220 parts by weight;
or, for the step (2), the initiator is one of 2,2′-azobis(isobutyronitrile), 2,2′-azobis-dimethyl-(2-methylpropionitrile), 2,2′-azobis(4-methoxy-2,4-dimethylvaleronitrile), 2,2′-azobis(2-cyclopropylpropionitrile), 2,2′-azobis(2,4-dimethylvaleronitrile), 1,1′-azobis(cyclohexanecarbonitrile), benzoyl peroxide, tert-butyl peroxybenzoate, di-tert-butyl perphthalate, tert-butyl peroxy-2-ethylhexanoate, tert-butyl peroxypivalate, tert-amyl peroxypivalate, and butyllithium;
or, for the step (2), the initiator is used in an amount of 1 to 10 wt %, where wt % refers to the ratio of the weight of the initiator to the combined weight of all monomers;
or, for the step (2), the mixed solvent is purged with nitrogen gas;
or, for the step (3), the method of adding components is using a peristaltic pump;
or, for the step (3), the polymerization reaction is performed at a temperature of 50 to 200° C.;
or, for the step (3), the duration of polymerization reaction is 5 to 7 hours.

3. A polymer used for preparing the bottom anti-reflective coating, wherein the polymer is prepared through the method for preparing the polymer according to claim 1.

4. The polymer according to claim 3, wherein the polymer has a weight-average molecular weight ranging from 2000 to 5000000;
or, the polymer has a number-average molecular weight ranging from 3000 to 6000;
or, the polymer has a polydispersity index ranging from 1 to 2.

5. A composition used for preparing the bottom anti-reflective coating, wherein the composition comprises the polymer according to claim 3, a solvent, and a photoacid generator.

6. The composition according to claim 5, wherein the solvent is one or more than one of an ether solvent, an ester solvent, an alcohol solvent, an aromatic solvent, a ketone solvent, and an amide solvent;
or, the quantity of the solvent used is 1000 to 2500 parts by weight;
or, the photoacid generator is one or more than one of an onium salt, a sulfonylimide derivative, and a disulfonyl diazomethane compound;
or, the photoacid generator is used in an amount of 0.01 to 20 parts by weight;
or, the polymer is used in an amount of 100 parts by weight.

7. The composition according to claim 6, wherein the onium salt is an iodonium salt, a sulfonium salt, or a crosslinkable onium salt;
or, the sulfonylimide derivative is one or more than one of N-(trifluoromethanesulfonyloxy) succinimide, N-(fluorobutanesulfonyloxy) succinimide, N-(camphorsulfonyloxy) succinimide, and N-(trifluoromethanesulfonyloxy)naphthalenediimide;
or, the disulfonyl diazomethane compound is one or more than one of bis(trifluoromethylsulfonyl) diazomethane, bis(cyclohexylsulfonyl) diazomethane, bis(phenylsulfonyl) diazomethane, bis(p-toluenesulfonyl) diazomethane, bis(2,4-dimethylphenylsulfonyl) diazomethane, and methylsulfonyl-p-toluenesulfonyl diazomethane.

8. The composition according to claim 5, wherein the composition further comprises additional components, and the additional components include a surfactant, and a leveling agent, and a polymer other than that polymer prepared through the method as follows:
wherein the method comprises the following steps:
(1) preheating solvent I;
(2) mixing a monomer of formula (A), a monomer of formula (B), a monomer of formula (C), a cross-linking agent of formula (L), and an initiator and solvent II to obtain a mixed solution; 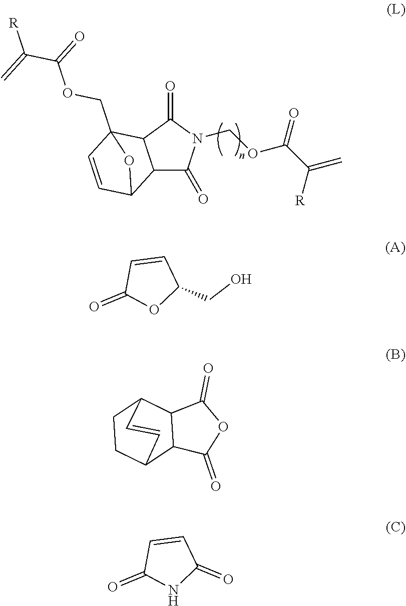
wherein R is H or methyl; n is 1 to 3;
the monomer of formula (A) is used in an amount of 500 to 1000 parts by weight; the monomer of formula (B) is used in an amount of 500 to 1000 parts by weight; the monomer of formula (C) is used in an amount of 500 to 1000 parts by weight; the cross-linking agent of formula (L) is used in an amount of 200 to 250 parts by weight;
(3) adding the mixed solution to a preheated solvent to initiate a polymerization reaction;
wherein step (1) and step (2) are in no particular order.

9. A method for preparing the composition used to prepare a bottom anti-reflective coating, wherein the method comprises the following step: mixing the various components of the composition according to claim 5.

10. The method for preparing the composition according to claim 9, wherein the method of mixing is stirring, or, the mixing conditions involve stirring at room temperature for 30 minutes; or following the mixing, an additional step of filtration is included.

11. The method for preparing the polymer according to claim 2, wherein,
for the step (1), the solvent I is one or more than one of an aromatic solvent, an ether solvent, a ketone solvent, an amide solvent, a sulfoxide solvent, and an ester solvent;
or, for the step (1), the solvent I is used in an amount of 1000 parts by weight;
or, for the step (1), if more than two types of solvents are used, the parts of different solvents are the same;
or, for the step (1), the solvent I is purged with nitrogen gas, and the purging is performed for 20 to 50 minutes;
or, for the step (1), the solvent I is preheated at 90° C.;
or, for the step (2), the solvent II is one or more than one of an aromatic solvent, an ether solvent, a ketone solvent, an amide solvent, a sulfoxide solvent, and an ester solvent;
or, for the step (2), the solvent I is used in an amount of 7000 parts by weight;
or, for the step (2), if more than two types of solvents are used, the parts of different solvents are the same;
or, for the step (2), the initiator is selected from 2,2′-azobis(isobutyronitrile) and 2,2′-azobis-dimethyl-(2-methylpropionitrile);
or, for the step (2), the initiator is used in an amount of 3 to 5 wt %;
or, for the step (2), the mixed solvent is purged with nitrogen gas, and the purging is performed for 30 minutes;
or, for the step (3), the method of adding components is using a peristaltic pump; the addition lasts for 2.5 hours;
or, for the step (3), the polymerization reaction is performed at a temperature of 60 to 150° C.;
or, for the step (3), the duration of polymerization reaction is 6 hours.

12. The method for preparing the polymer according to claim 11, wherein,
for the step (1), the aromatic solvent is selected from toluene and benzene;
or, for the step (1), the ether solvent is tetrahydrofuran;
or, for the step (1), the ketone solvent is 2-heptanone;
or, for the step (1), the amide solvent is N,N′-dimethylformamide;
or, for the step (1), the sulfoxide solvent is dimethyl sulfoxide;
or, for the step (1), the ester solvent is selected from ethyl lactate and 1-methoxy-2-propyl acetate;
or, for the step (1), the solvent I is purged with nitrogen gas, and the purging is performed for 30 minutes;
or, for the step (2), the aromatic solvent is selected from toluene and benzene;
or, for the step (2), the ether solvent is tetrahydrofuran;
or, for the step (2), the ketone solvent is 2-heptanone;
or, for the step (2), the amide solvent is N,N′-dimethylformamide;
or, for the step (2), the sulfoxide solvent is dimethyl sulfoxide;
or, for the step (2), the ester solvent is selected from ethyl lactate and 1-methoxy-2-propyl acetate;
or, for the step (2), the initiator is 2,2′-azobis(isobutyronitrile);
or, for the step (3), the polymerization reaction is performed at a temperature of y 80 to 120° C.

13. The method for preparing the polymer according to claim 12, wherein,
for the step (1), the solvent I is selected from amide solvents and ketone solvents, such as N,N′-dimethylformamide and 2-heptanone;
or, for the step (2), the organic solvent is selected from amide solvents and ketone solvents.

14. The method for preparing the polymer according to claim 13, wherein,
for the step (1), the solvent I is N,N′-dimethylformamide and 2-heptanone;
or, for the step (2), the organic solvent is N,N′-dimethylformamide and 2-heptanone.

15. The polymer according to claim 4, wherein the polymer has a weight-average molecular weight ranging from 3000 to 100000;
or, the polymer has a number-average molecular weight of 3009, 3479, 4593, 4783, 5609, 5794, or 5885;
or, the polymer has a polydispersity index of 1.10, 1.12, 1.14, 1.20, 1.29, 1.38, 1.72, or 1.73.

16. The polymer according to claim 15, wherein the polymer has a weight-average molecular weight of 5220, 5237, 5974, 6155, 6166, 6355, 6589, or 6931.

17. The composition according to claim 6, wherein
the ether solvent is one or more than one of propylene glycol monobutyl ether, ethylene glycol monomethyl ether, ethylene glycol monoethyl ether, diethylene glycol monomethyl ether, diethylene glycol monoethyl ether, and propylene glycol monomethyl ether;
or, the ester solvent is one or more than one of propylene glycol monobutyl ether acetate, methyl cellosolve acetate, ethyl cellosolve acetate, propylene glycol monomethyl ether acetate, propylene glycol propyl ether acetate, ethyl 2-hydroxypropionate, ethyl 2-hydroxy-2-methylpropionate, ethyl ethoxyacetate, ethyl hydroxyacetate, methyl 2-hydroxy-3-methylbutyrate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, and butyl lactate;
or, the alcohol solvent is propylene glycol;
or, the aromatic solvent is selected from toluene and xylene;
or, the ketone solvent is one or more than one of 2-butanone, cyclopentanone, and cyclohexanone;
or, the amide solvent is one or more than one of N,N-dimethylformamide, N,N-dimethylacetamide, and N-methyl-2-pyrrolidone;
or, the quantity of the solvent used is 1200 to 2000 parts by weight;
or, the photoacid generator is used in an amount of 1 to 15 parts by weight;
or, the onium salt is an iodonium salt; the iodonium salt is one or more than one of diphenyliodonium hexafluorophosphate, diphenyliodonium trifluoromethanesulphonate, diphenyliodonium nonafluorobutanesulfonate, diphenyliodonium perfluorooctanesulfonate, diphenyliodonium camphorsulfonate, bis(4-tert-butylphenyl)iodonium camphorsulfonate, and bis(4-tert-butylphenyl)iodonium trifluoromethanesulfonate;
or, the onium salt is a sulfonium salt; the sulfonium salt is one or more than one of triphenylsulfonium hexafluoroantimonate, triphenylsulfonium nonafluorobutanesulfonate, triphenylsulfonium camphorsulfonate, and triphenylsulfonium trifluoromethanesulfonate;
or, the onium salt is a crosslinkable onium salt; the crosslinkable onium salt is one or more than one of bis(4-hydroxyphenyl)(phenyl)sulfonium trifluoromethanesulfonate, bis(4-hydroxyphenyl)(phenyl)sulfonium 1,1,2,2,3,3,4,4,4-nonafluorobutane-1-sulfonate, phenylbis(4-(2-(vinyloxy)ethoxy)-phenyl)sulfonium 1,1,2,2,3,3,4,4-octafluorobutane-1,4-disulfonate, and tris(4-(2-(vinyloxy)ethoxy)-phenyl)sulfonium 1,1,2,2,3,3,4,4-octafluorobutane-1,4-disulfonate.

18. The composition according to claim 17, wherein
the solvent is selected from propylene glycol monobutyl ether and propylene glycol monobutyl ether acetate;
or, the quantity of the solvent used is 1500 to 1800 parts by weight;
or, the photoacid generator is used in an amount of 5 to 10 parts by weight;
or, the onium salt is a sulfonium salt; the sulfonium salt is selected from triphenylsulfonium hexafluoroantimonate and triphenylsulfonium trifluoromethanesulfonate.

19. The method for preparing the composition according to claim 10, wherein the filtration is conducted using a filter, with the pore size of the filter ranging from 0.2 to 0.05 m.

20. A bottom anti-reflective coating, wherein the bottom anti-reflective coating is prepared from the composition of claim 5.
